(19) United States
(12) Patent Application Publication
(10) Pub. No.: US 2014/0289578 A1
(43) Pub. Date: Sep. 25, 2014

(54) SCAN CIRCUIT HAVING FIRST SCAN FLIP-FLOPS AND SECOND SCAN FLIP-FLOPS

(71) Applicant: FUJITSU LIMITED, Kawasaki-shi (JP)

(72) Inventor: Itsumi Sugiyama, Kawasaki (JP)

(21) Appl. No.: 14/298,061

(22) Filed: Jun. 6, 2014

Related U.S. Application Data
(63) Continuation of application No. PCT/JP2011/078614, filed on Dec. 9, 2011.

(51) Int. Cl. G01R 31/3177

(52) U.S. Cl. CPC G01R 31/3177
USPC 714/727

(57) ABSTRACT

A scan circuit includes first scan flip-flops each including a first logic circuit to receive a plurality of control signals in addition to a scan input signal and a data input signal, and second scan flip-flops each including a second logic circuit to receive the plurality of control signals in addition to a scan input signal and a data input signal, wherein the first scan flip-flops and the second scan flip-flops are connected in series, and the plurality of control signals include only a one-bit reset signal and control signals whose purpose is other than an initialization purpose, and wherein the plurality of control signals are set to a predetermined combination of logic values to cause each of the first scan flip-flops to be initialized to “0” by the first logic circuit and each of the second scan flip-flops to be initialized to “1” by the second logic circuit.

### CROSS-REFERENCE TO RELATED APPLICATIONS

This application is a continuation application of International Application PCT/JP2011/078614 filed on Dec. 9, 2011, and designated the U.S., the entire contents of which are incorporated herein by reference.

### FIELD

The disclosures herein generally relate to semiconductor integrated circuits, and particularly relate to a semiconductor integrated circuit having a test function.

### BACKGROUND

In a scan test method used in an LSI (i.e., large scale integration) circuit, a plurality of flip-flops constituting the internal circuitry of the LSI are connected in cascade to form a scan chain, and data are input into and output from the scan chain to test the internal circuitry. Each flip-flop constituting the internal circuitry has a scan input node and a scan output node. The scan output node of a given flip-flop is coupled to the scan input node of another flip-flop in such a manner that flip-flops are connected in cascade to constitute a flip-flop chain. In a test operation mode, each scan flip-flop in the scan path loads input data applied to its scan input node, and outputs the stored data from its scan output node in synchronization with a clock signal, in response to a signal indicative of a scan enable state applied from an external device. In this manner, data states inside the LSI circuit are retrieved through the scan operation, and are compared with expected values obtained in advance by logic simulation, thereby detecting the presence of a failure and the location of such a failure.

There are two scan operation methods. One is MUX-D and the other is LSSD (i.e., level sensitive scan design). The LSSD method applies a scan-dedicated clock signal, which is independent of a system clock, to a master latch and a slave latch separately. This method is robust against manufacturing variation that exists in transistor characteristics, and is thus suitable for an LSI test that is performed in a stage where the process for manufacturing semiconductor devices is not yet matured.

During the period in which the semiconductor device manufacturing process is in its development phase, a single LSI is often subjected to failure diagnosis to detect not only the presence of failures but also the cause of failures, thereby improving a fabrication yield. In so doing, the scan test compares the internal states with their expected values to estimate the locations of failures, thereby investigating the causes of failures. However, a failure may occur in a circuit relating to the scan operations. In such a case, the resulting error may cause the scan outputs of the LSI to be fixed to a constant value, for example, which makes it difficult to estimate the locations of failures.

In order to perform a failure diagnosis with respect to the scan circuit portion, data having “0”s and “1”s alternating with each other may be set in the scan chain, followed by observing the scan outputs. However, when data having “0”s and “1”s alternating with each other are input into the scan input of the LSI, and are shifted to be set in the scan chain, all the data may be changed to “1”s somewhere along the scan chain when there is a failure in the scan circuit. As a result, all the data of the scan output end up being fixed to “1”s, which indicates the presence of a failure, but does not provide information on the location of the failure. In order to make it possible to estimate the location of failure, data may be directly set in the flip-flops such that alternating “0”s and “1”s are in existence in the scan chain, rather than setting initial values to the flip-flops through a scan shift operation. With this arrangement, the scan outputs initially consist of alternating “0”s and “1”s, and are then fixed to “1”s after some point along the output data string. The location of a failure that causes values to be fixed to “1”s can thus be identified. However, the provision of a dedicated write circuit as disclosed in Patent Document 1 for the purpose of setting data having alternating “0”s and “1”s as described above is not preferable because the provision of such a circuit leads to increases in circuit size and in the areas for signal lines.

There is a method that diagnoses a scan path by refraining from performing an initialization-purpose resetting with respect to the scan flip-flops, based on an expectation that the states of the flip-flops are random immediately upon the power-on (see Patent Document 1). Such a method allows a check to be made as to whether a failure exists. Since the expected values are unknown, however, it is difficult to estimate the location of a failure with certainty.
[Patent Document 1] Japanese Laid-open Patent Publication No. H5-164820
[Patent Document 2] Japanese Laid-open Patent Publication No. H6-242190
[Patent Document 3] Japanese Laid-open Patent Publication No. 2004-12399

### SUMMARY

According to an aspect of the embodiment, a scan circuit includes a plurality of first scan flip-flops each including a first logic circuit and each configured to receive a plurality of control signals in addition to a scan input signal and a data input signal that are to be latched, and a plurality of second scan flip-flops each including a second logic circuit and each configured to receive the plurality of control signals in addition to a scan input signal and a data input signal that are to be latched, wherein the first scan flip-flops and the second scan flip-flops are connected in series, and the plurality of control signals include only a one-bit reset signal and control signals whose purpose is other than an initialization purpose, and wherein the plurality of control signals are set to a predetermined combination of logic values to cause each of the first scan flip-flops to be initialized to “0” by the first logic circuit and to cause each of the second scan flip-flops to be initialized to “1” by the second logic circuit.

According to an aspect of the embodiment, a semiconductor integrated circuit includes a scan input terminal, a scan output terminal, a plurality of first scan flip-flops each including a first logic circuit and each configured to receive a plurality of control signals in addition to a scan input signal and a data input signal that are to be latched, and a plurality of second scan flip-flops each including a second logic circuit and each configured to receive the plurality of control signals in addition to a scan input signal and a data input signal that are to be latched, and a circuit connected to the plurality of first scan flip-flops and to the plurality of second scan flip-flops, wherein the first scan flip-flops and the second scan flip-flops are connected in series between the scan input terminal and the scan output terminal, and the plurality of control signals include only a one-bit reset signal and control signals whose purpose is other than an initialization purpose, and wherein the plurality of control signals are set to a predetermined combination of logic values to cause each of the first scan flip-flops to be initialized to “0” by the first logic circuit and to cause each of the second scan flip-flops to be initialized to “1” by the second logic circuit.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a drawing illustrating an example of the related-art configuration of a flip-flop provided with the LSSD-type scan function;

FIG. 2 is a timing chart for explaining the operation of the scan flip-flop illustrated in FIG. 1;

FIGS. 3A and 3B are drawings illustrating the configuration of a first embodiment of flip-flops provided with the LSSD-type scan function;

FIG. 4 is a timing chart illustrating the waveforms of input signals used in the normal operation mode of the flip-flops with the scan function illustrated in FIGS. 3A and 3B;

FIG. 5 is a timing chart illustrating the waveforms of input and output signals used in the initialization operation of the scan operation mode of the flip-flops with the scan function illustrated in FIGS. 3A and 3B;

FIG. 6 is a timing chart illustrating the waveforms of input and output signals used in the scan operation of the scan operation mode of the flip-flops with the scan function illustrated in FIGS. 3A and 3B;

FIG. 7 is a drawing illustrating an example of a scan chain in which the flip-flops with the scan function illustrated in FIGS. 3A and 3B are arranged;

FIG. 8 is a drawing illustrating an example of the configuration of a semiconductor integrated circuit in which a scan chain similar to the scan chain illustrated in FIG. 7 is used;

FIGS. 9A and 9B are drawings illustrating examples of the first logic circuit illustrated in FIG. 3A and the second logic circuit illustrated in FIG. 3B;

FIGS. 10A and 10B are drawings illustrating the configuration of a second embodiment of flip-flops provided with the LSSD-type scan function;

FIG. 11 is a timing chart illustrating the waveforms of input signals used in each operation mode of the flip-flops with the scan function illustrated in FIGS. 10A and 10B;

FIGS. 12A and 12B are drawings illustrating the configuration of an embodiment of flip-flops provided with the MUX-D-type scan function; and

FIG. 13 is a timing chart illustrating the waveforms of input signals used in each operation mode of the flip-flops with the scan function illustrated in FIGS. 12A and 12B.

### DESCRIPTION OF EMBODIMENTS

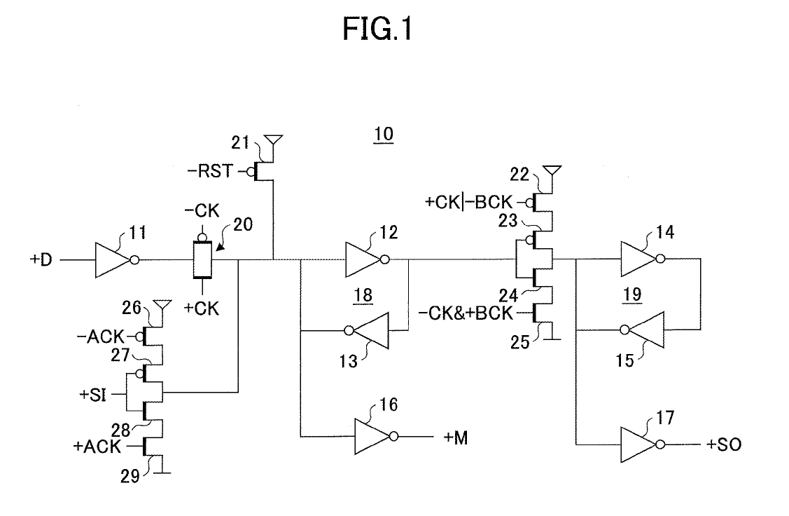

FIG. 1 is a drawing illustrating an example of the related-art configuration of a flip-flop provided with the LSSD-type scan function. The flip-flop illustrated in FIG. 1 includes inverters 11 through 17, a transmission gate 20, PMOS transistors through 23, NMOS transistors 24 and 25, PMOS transistors 26 and 27, and NMOS transistors 28 and 29. Each of the inverters 12 and 13 receives the output of the other as its input, so that these inverters function as a latch 18. Further, each of the inverters 14 and 15 receives the output of the other as its input, so that these inverters function as a latch 19. The transmission gate 20 includes a PMOS transistor and an NMOS transistor that are connected to each other in parallel. The transmission gate 20 becomes conductive when a clock signal +CK is HIGH and its inverted signal −CK is LOW. Upon the transmission gate 20 becoming conductive, the latch loads a value that is an inverse of a data input +D. When a clock signal ACK is HIGH and its inverted signal −ACK is LOW, the latch 18 loads an inverse of a scan input +SI.

The gate of the PMOS transistor 22 receives an OR operation between an inverted signal −BCK of a clock signal +BCK and the clock signal +CK. The gate of the NMOS transistor 25 receives an AND operation between the clock signal +BCK and the inverted signal −CK of the clock signal +CK.

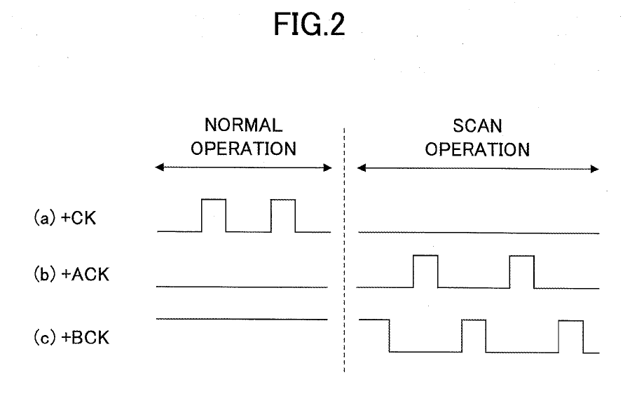

FIG. 2 is a timing chart for explaining the operation of the scan flip-flop illustrated in FIG. 1. The timing chart of FIG. 2 illustrates the waveforms of input signals used in the case of a normal operation mode and the waveforms of input signals used in the case of a scan operation mode. FIG. 2-(a) illustrates +CK, and FIG. 2-(b) illustrates +ACK, with FIG. 2-(c) illustrating +BCK.

In the normal operation mode, the latch 18 loads data at the data input +D, and outputs the loaded data at a data output +M. In this normal operation mode, the clock signal +ACK is fixed to LOW (i.e., its inverted signal −ACK is fixed to HIGH), and the clock signal +BCK is fixed to HIGH (i.e., its inverted signal −BCK is fixed to LOW). In this state, the clock signal +CK is set to HIGH and LOW alternately. The latch 18 loads the data input +D at the time the clock signal +CK is HIGH (i.e., its inverted signal −CK is LOW). The data of the latch 18 is transferred to the latch 19 at the time the clock signal +CK subsequently becomes LOW (i.e., its inverted signal −CK is HIGH). The data stored in the latch 18 is output as the data output +M, and the data stored in the latch 19 is output as a scan output +SO.

In the scan operation mode, data at the scan input +SI is loaded to the latch 18, and the loaded data is then transferred to the latch 19, followed by outputting the transferred data at the scan output +SO. In this scan operation mode, the clock signal +CK is fixed to LOW (i.e., its inverted signal −CK is fixed to HIGH). In this state, the clock signal +ACK and the clock signal +BCK are alternately set to HIGH to cause data to be loaded to the latch 18 and the data to be subsequently transferred from the latch 18 to the latch 19. If the clock signal +ACK and the clock signal +BCK are simultaneously HIGH, a through path is established between the scan input +SI and the scan output +SO, resulting in the latch failing to hold the value that is supposed to be held. Accordingly, the clock signal +ACK and the clock signal +BCK are prohibited from being HIGH at the same time.

A reset signal −RST is a control signal for initializing the flip-flop as part of the system operations. Setting the reset signal −RST to “0” serves to initialize the latch 18 to “0”. Namely, initialization is performed such that the output of the inverter 12 of the latch 18 is set to “0”.

In the flip-flop with the scan function illustrated in FIG. 1, the latch 18 can be initialized to “0” by the reset signal (i.e., initialized such that the scan output +SO is set to “0”). As was previously described, however, it is preferable to be able to set data having alternating “0”s and “1”s in the scan chain as initial values for the purpose of reliably identifying the location of a failure.

In the following, embodiments of the invention will be described with reference to the accompanying drawings.

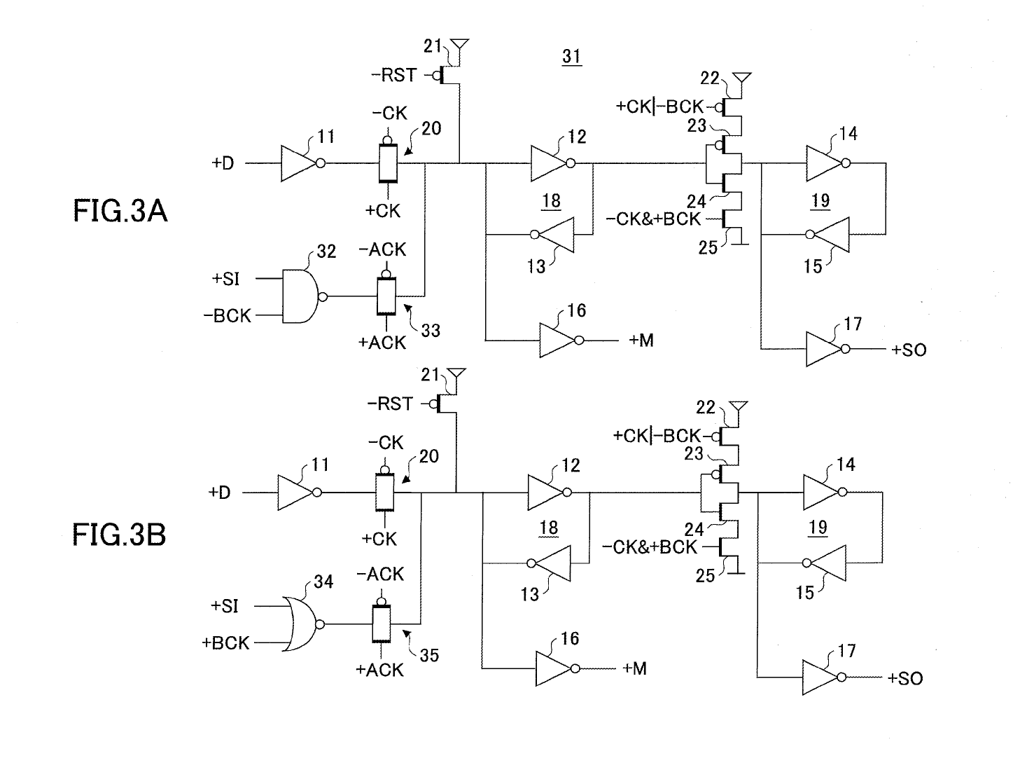

FIGS. 3A and 3B are drawings illustrating the configuration of a first embodiment of flip-flops provided with the LSSD-type scan function. In FIGS. 3A and 3B, the same or corresponding elements as those of FIG. 1 are referred to by the same or corresponding numerals, and a description thereof will be omitted as appropriate.

The flip-flop with the scan function illustrated in FIG. 3A is a first flip-flop that has a circuit configuration capable of setting “0” as an initial value. Namely, this first flip-flop is initialized such that the scan output +SO is set to “0”. This flip-flop includes a first logic circuit (i.e., a NAND gate 32 and a transmission gate 33), and receives a plurality of control signals (i.e., +CK, +ACK, +BCK, −RST) in addition to the scan input signal +SI and the data input signal +D that are to be latched. Inverses of the signals +CK, +ACK, and +BCK may be generated by use of inverters, which are omitted from illustration. The plurality of control signals only include the one-bit reset signal −RST and the control signals +CK, +ACK, and +BCK whose purpose (i.e., the clock synchronization purpose in this example) is other than the initialization purpose. More specifically, the plurality of control signals include the one-bit reset signal −RST, the first clock signal +CK for inputting and outputting a data input signal, and the second and third clock signals +ACK and +BCK for inputting and outputting a scan input signal. Setting the plurality of control signals to a certain combination of logic values causes the first scan flip-flop illustrated in FIG. 3A to be initialized to “0” by the first logic circuit (i.e., the NAND gate 32 and the transmission gate 33).

The flip-flop with the scan function illustrated in FIG. 3B is a second flip-flop that has a circuit configuration capable of setting “1” as an initial value. Namely, this second flip-flop is initialized such that the scan output +SO is set to “1”. This flip-flop includes a second logic circuit (i.e., a NOR gate 34 and a transmission gate 35), and receives the previously-noted plurality of control signals (i.e., +CK, +ACK, +BCK, −RST) in addition to the scan input signal +SI and the data input signal +D that are to be latched. Inverses of the signals +CK, +ACK, and +BCK may be generated by use of inverters, which are omitted from illustration. Setting the plurality of control signals to a certain combination of logic values causes the second scan flip-flop illustrated in FIG. 3B to be initialized to “1” by the second logic circuit (i.e., the NOR gate 34 and the transmission gate 35).

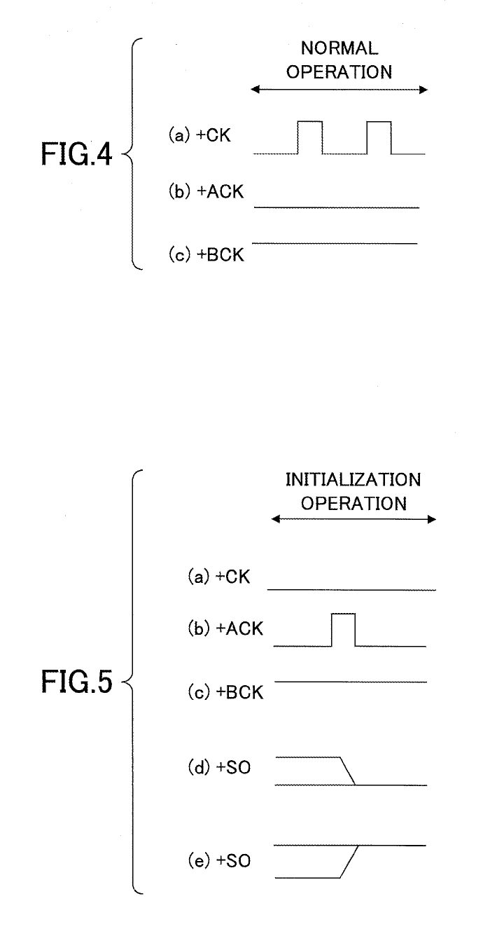

FIG. 4 is a timing chart illustrating the waveforms of input signals used in the normal operation mode of the flip-flops with the scan function illustrated in FIGS. 3A and 3B. FIG. 4-(a) illustrates +CK, and FIG. 4-(b) illustrates +ACK, with FIG. 4-(c) illustrating +BCK.

In the normal operation mode, the latch 18 loads data at the data input +D, and outputs the loaded data at the data output +M. In this normal operation mode, the clock signal +ACK is fixed to LOW (i.e., its inverted signal −ACK is fixed to HIGH), and the clock signal +BCK is fixed to HIGH (i.e., its inverted signal −BCK is fixed to LOW). In this state, the clock signal +CK is set to HIGH and LOW alternately. The latch 18 loads the data input +D at the time the clock signal +CK is HIGH (i.e., its inverted signal −CK is LOW). The data of the latch is transferred to the latch 19 at the time the clock signal +CK subsequently becomes LOW (i.e., its inverted signal −CK is HIGH). The data stored in the latch 18 is output as the data output +M, and the data stored in the latch 19 is output as the scan output +SO.

FIG. 5 is a timing chart illustrating the waveforms of input and output signals used in the initialization operation of the scan operation mode of the flip-flops with the scan function illustrated in FIGS. 3A and 3B. FIG. 5-(a) illustrates +CK, and FIG. 5-(b) illustrates +ACK, with FIG. 5-(c) illustrating +BCK. Further, FIG. 5-(d) illustrates the scan output +SO of the flip-flop illustrated in FIG. 3A, and FIG. 5-(e) illustrates the scan output +SO of the flip-flop illustrated in FIG. 3B.

In the initialization operation of the scan operation mode, the flip-flops with the scan function illustrated in FIGS. 3A and 3B are initialized to “0” and “1”, respectively. In the scan operation mode, the clock signal +CK is fixed to LOW (i.e., its inverted signal −CK is fixed to HIGH). In the initialization operation, the clock signal +ACK and the clock signal +BCK are both set to HIGH. With this arrangement in the first flip-flop with the scan function illustrated in FIG. 3A, the output value “1” of the NAND gate 32 responsive to LOW of −BCK is stored in the latch 18 through the transmission gate 33. Namely, initialization is performed such that the output of the inverter 12 of the latch 18 is set to “0”. Since the clock signal +BCK and its inverted signal −BCK are HIGH and LOW, respectively, the data stored in the latch 18 is immediately stored in the latch 19 also, so that the scan output +SO is set to “0”. In the second flip-flop with the scan function illustrated in FIG. 3B, the output value “0” of the NOR gate 34 responsive to HIGH of +BCK is stored in the latch 18 through the transmission gate 35. Namely, initialization is performed such that the output of the inverter 12 of the latch 18 is set to “1”. Since the clock signal +BCK and its inverted signal −BCK are HIGH and LOW, respectively, the data stored in the latch 18 is immediately stored in the latch 19 also, so that the scan output +SO is set to “1”. In this manner, the first flip-flop is set to an initial value of “0”, and the second flip-flop is set to an initial value of “1”.

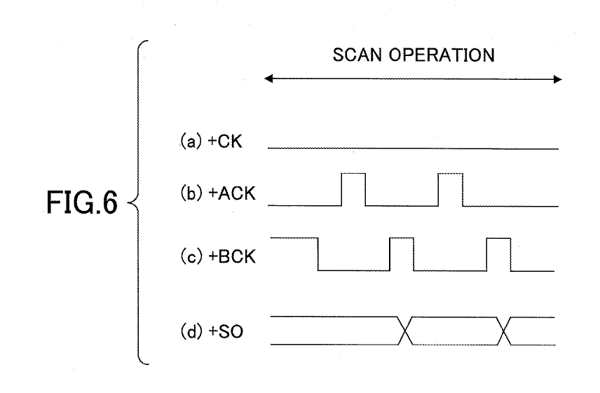

FIG. 6 is a timing chart illustrating the waveforms of input and output signals used in the scan operation of the scan operation mode of the flip-flops with the scan function illustrated in FIGS. 3A and 3B. FIG. 6-(a) illustrates +CK, and FIG. 6-(b) illustrates +ACK, with FIG. 6-(c) illustrating +BCK. Further, FIG. 6-(d) illustrates the scan output +SO of the flip-flops illustrated in FIGS. 3A and 3B.

In the scan operation mode, data at the scan input +SI is loaded to the latch 18, and the loaded data is then transferred to the latch 19, followed by outputting the transferred data at the scan output +SO. In this scan operation mode, the clock signal +CK is fixed to LOW (i.e., its inverted signal −CK is fixed to HIGH). In this state, the clock signal +ACK and the clock signal +BCK are alternately set to HIGH to cause data to be loaded to the latch 18 and the data to be subsequently transferred from the latch 18 to the latch 19. Each time a HIGH pulse appears in the clock signal +BCK the data of the scan output +SO is switched to new data.

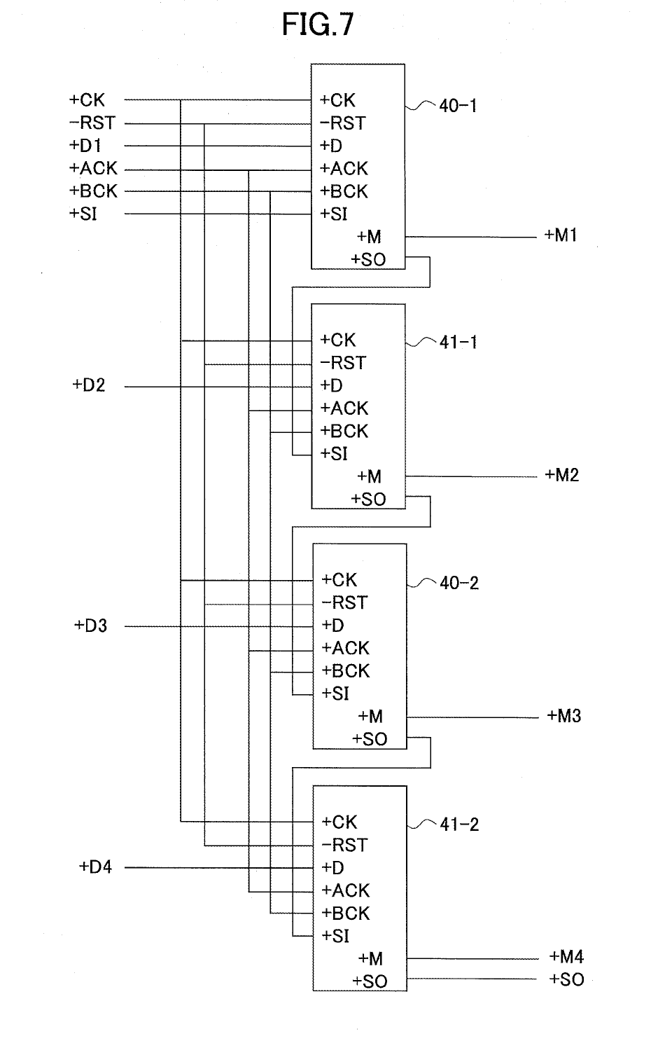

FIG. 7 is a drawing illustrating an example of a scan chain in which the flip-flops with the scan function illustrated in FIGS. 3A and 3B are arranged. In FIG. 7, each of the flip-flops 40-1 and 40-2 is the first flip-flop with the scan function illustrated in FIG. 3A, and is initialized such that the scan output +SO is set to “0”. Each of the flip-flops 41-1 and 41-2 is the second flip-flop with the scan function illustrated in FIG. 3B, and is initialized such that the scan output +SO is set to “1”. In the scan chain, the scan output +SO of a given stage is connected to the scan input +SI of the next stage, such that first scan flip-flops and second scan flip-flops are alternately connected in series. With this arrangement, a pattern of initial values having “0”s and “1”s alternating with each other can be set in the scan chain. Each of the flip-flops 40-1, 40-2, 41-1 and 41-2 receives the same plurality of control signals (i.e., +CK, +ACK, +BCK, and −RST).

In the example illustrated in FIG. 7, the first flip-flops and the second flip-flops alternate with each other and are connected in series. Such an example is not intended to be limiting. For example, the first flip-flops and the second flip-flops may be connected in series such that the pattern of initial values is as follows: 1, 0, 1, 1, 0, 1, 0, 1, 1, 0, and so on.

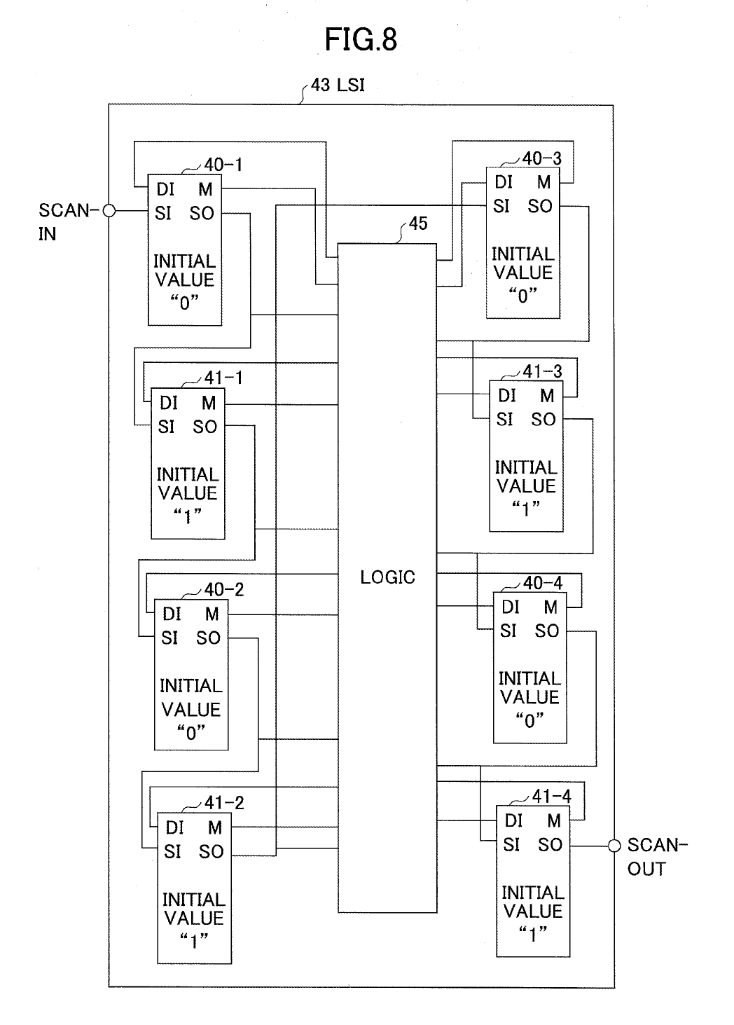

FIG. 8 is a drawing illustrating an example of the configuration of a semiconductor integrated circuit in which a scan chain similar to the scan chain illustrated in FIG. 7 is used. In FIG. 8, each of the flip-flops 40-1 through 40-4 is the first flip-flop with the scan function illustrated in FIG. 3A, and is initialized such that the scan output +SO is set to “0”. Each of the flip-flops 41-1 through 41-4 is the second flip-flop with the scan function illustrated in FIG. 3B, and is initialized such that the scan output +SO is set to “1”. In the scan chain, the scan output +SO of a given stage is connected to the scan input +SI of the next stage, such that first scan flip-flops and second scan flip-flops are alternately connected in series. In the example illustrated in FIG. 8, further, a logic circuit 45 is connected to the flip-flops 40-1 through 40-4 and the flip-flops 41-1 through 41-4. Specifically, the data input DI and data output M of each flip-flop are connected to the logic circuit 45. In this manner, an LSI 43 illustrated in FIG. 8 is configured such that all or part of the flip-flops embedded therein are provided with the scan function, and such that these flip-flops with the scan function are connected in series to form a scan chain.

Each control signal is controlled as illustrated in FIG. 5 to set “0” in the flip-flops 40-1 through 40-4 and to set “1” in the flip-flops 41-1 through 41-4. Thereafter, each control signal is controlled as illustrated in FIG. 6 to shift data in the scan chain and to cause the data to be successively output from a data output terminal SCAN-OUT. The fact that the output data consist of “0”s and “1”s alternating with each other in the same manner as in the initial setting pattern warrants an estimate that the scan circuits of the scan chain are free from failures. The fact that the output data initially consist of “0”s and “1”s alternating with each other but subsequently consist of a single value fixed to “0” or “1” allows an estimate to be made with regard to the position of a failure in the scan circuits based on the position of data at which the output data is fixed. The output data pattern may not be fixed to either “0” or “1”, but may still be different from the initial setting pattern having “0”s and “1”s alternating with each other. In such a case, the position of data that is different from the initial setting pattern may give a clue as to the position of a failure in the scan circuits.

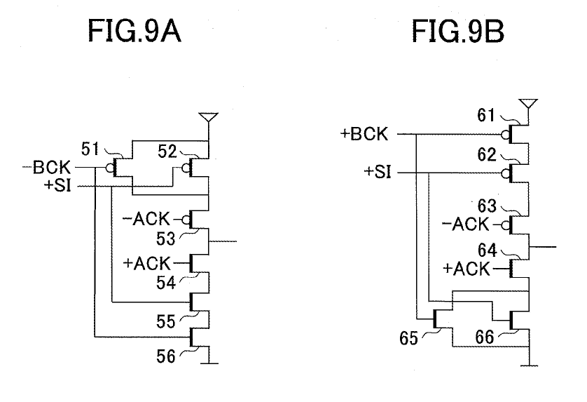

FIG. 9A is a drawing illustrating an example of the first logic circuit illustrated in FIG. 3A. The first logic circuit includes the NAND gate 32 and the transmission gate 33. The NAND gate 32 and the transmission gate 33 may be combined into a single circuit that implements the same logic by use of a smaller circuit area with a fewer number of interconnect lines. The first logic circuit illustrated in FIG. 9A includes PMOS transistors 51 through 53 and NMOS transistors 54 through 56. The circuit structure illustrated in FIG. 9A can be implemented by use of a smaller circuit size with a fewer number of interconnect lines than in the case in which the NAND gate 32 and the transmission gate 33 are laid out as separate circuits.

FIG. 9B is a drawing illustrating an example of the second logic circuit illustrated in FIG. 3B. The second logic circuit includes the NOR gate 34 and the transmission gate 35. The NOR gate 34 and the transmission gate 35 may be combined into a single circuit that implements the same logic by use of a smaller circuit area with a fewer number of interconnect lines. The second logic circuit illustrated in FIG. 9B includes PMOS transistors 61 through 63 and NMOS transistors 64 through 66. The circuit structure illustrated in FIG. 9B can be implemented by use of a smaller circuit size with a fewer number of interconnect lines than in the case in which the NOR gate 34 and the transmission gate 35 are laid out as separate circuits.

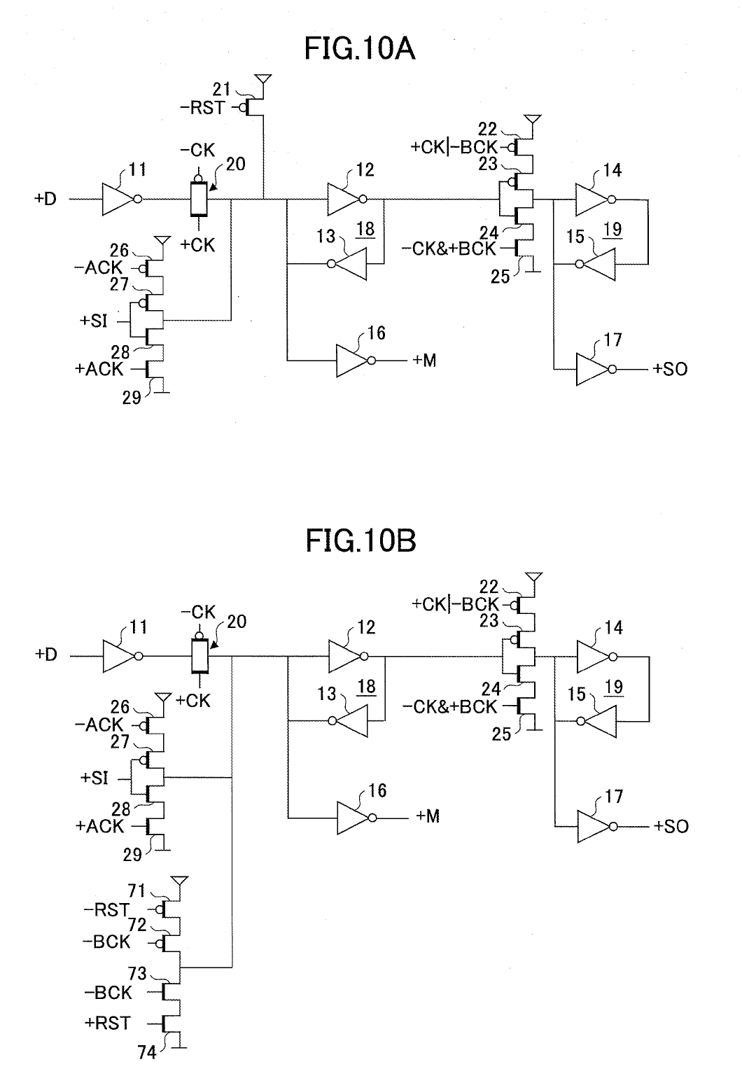

FIGS. 10A and 10B are drawings illustrating the configuration of a second embodiment of flip-flops provided with the LSSD-type scan function. In FIGS. 10A and 10B, the same or corresponding elements as those of FIG. 1 are referred to by the same or corresponding numerals, and a description thereof will be omitted as appropriate.

The flip-flop with the scan function illustrated in FIG. 10A is a first flip-flop that has a circuit configuration capable of setting “0” as an initial value. Namely, this first flip-flop is initialized such that the scan output +SO is set to “0”. This flip-flop includes a first logic circuit (i.e., a PMOS transistor 21), and receives a plurality of control signals (i.e., +CK, +ACK, +BCK, −RST) in addition to the scan input signal +SI and the data input signal +D that are to be latched. Inverses of the signals +CK, +ACK, and +BCK may be generated by use of inverters, which are omitted from illustration. Setting the plurality of control signals to a certain combination of logic values causes the first scan flip-flop illustrated in FIG. 10A to be initialized to “0” by the first logic circuit (i.e., the PMOS transistor 21). It may be noted that the first flip-flop illustrated in FIG. 10A has the same or similar circuit configuration as the related-art flip-flop with the LSSD-type scan function illustrated in FIG. 1.

The flip-flop with the scan function illustrated in FIG. 10B is a second flip-flop that has a circuit configuration capable of setting “1” as an initial value. Namely, this second flip-flop is initialized such that the scan output +SO is set to “1”. This flip-flop includes, instead of the first logic circuit (i.e., the PMOS transistor 21), a second logic circuit (i.e., PMOS transistors 71 and 72 and NMOS transistors 73 and 74). Further, this flip-flop receives the previously-noted plurality of control signals (i.e., +CK, +ACK, +BCK, −RST) in addition to the scan input signal +SI and the data input signal +D that are to be latched. Inverses of the signals +CK, +ACK, and +BCK may be generated by use of inverters, which are omitted from illustration. Setting the plurality of control signals to a certain combination of logic values causes the second scan flip-flop illustrated in FIG. 10B to be initialized to “1” by the second logic circuit (i.e., the PMOS transistors 71 and 72 and the NMOS transistors 73 and 74).

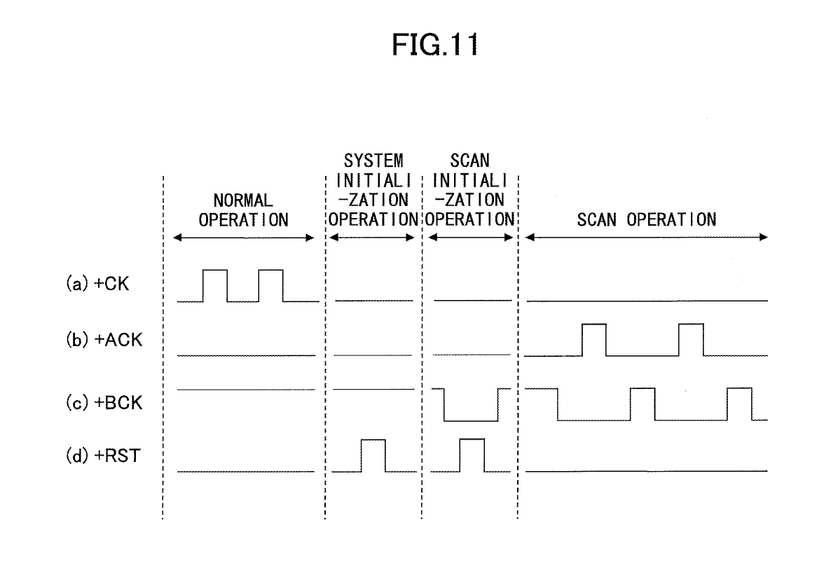

FIG. 11 is a timing chart illustrating the waveforms of input signals used in each operation mode of the flip-flops with the scan function illustrated in FIGS. 10A and 10B. FIG. 11-(a) illustrates +CK, and FIG. 11-(b) illustrates +ACK, with FIG. 11-(c) illustrating +BCK. Further, FIG. 11-(d) illustrates +RST.

In the normal operation mode, the latch 18 loads data at the data input +D, and outputs the loaded data at the data output +M. In this normal operation mode, the clock signal +ACK is fixed to LOW (i.e., its inverted signal −ACK is fixed to HIGH), and the clock signal +BCK is fixed to HIGH (i.e., its inverted signal −BCK is fixed to LOW). Further, the reset signal +RST is fixed to LOW (i.e., its inverted signal −RST is fixed to HIGH). In this state, the clock signal +CK is set to HIGH and LOW alternately. The latch 18 loads the data input +D at the time the clock signal +CK is HIGH (i.e., its inverted signal −CK is LOW). The data of the latch 18 is transferred to the latch 19 at the time the clock signal +CK subsequently becomes LOW (i.e., its inverted signal −CK is HIGH). The data stored in the latch 18 is output as the data output +M, and the data stored in the latch 19 is output as the scan output +SO.

In the system initialization operation, initialization is performed to reset the entirety of the LSI 43 illustrated in FIG. 8, for example. In this system initialization operation, the clock signals +CK, +ACK, and +BCK are fixed to LOW, LOW, and HIGH, respectively. In this state, the reset signal +RST is set to HIGH (i.e., its inverted signal −RST is set to LOW), thereby performing a reset operation. Specifically, the flip-flop with the scan function illustrated in FIGS. 10A and 10B is initialized such that the input node of the inverter 12 of the latch 18 is set to “1”.

In the initialization operation of the scan operation mode, the flip-flops with the scan function illustrated in FIGS. 10A and 10B are initialized to “0” and “1”, respectively. In the scan operation mode, the clock signal +CK is fixed to LOW (i.e., its inverted signal −CK is fixed to HIGH), and the clock signal +ACK is fixed to LOW (i.e., its inverted signal −ACK is fixed to HIGH). In the initialization operation, the clock signal +BCK is set to LOW (i.e., its inverted signal −BCK is set to HIGH), followed by setting the reset signal +RST to HIGH (i.e., setting −RST to LOW). Thereafter, the reset signal +RST is returned to LOW (i.e., −RST is returned to HIGH), followed by returning the clock signal +BCK to HIGH (i.e., returning −BCK to LOW). With this arrangement, the PMOS transistor 21 in the first flip-flop with the scan function illustrated in FIG. 10A becomes conductive in response to the LOW state of −RST, so that the latch 18 is initialized. Namely, initialization is performed such that the output of the inverter 12 of the latch 18 is set to “0”. As the clock signal +BCK and its inverted signal −BCK return to HIGH and LOW, respectively, the data stored in the latch 18 is stored in the latch 19, so that the scan output +SO is set to “0”. Further, the NMOS transistors 73 and 74 in the second flip-flop with the scan function illustrated in FIG. 10B become conductive in response to the HIGH state of +RST and −BCK, so that the latch 18 is initialized. Namely, initialization is performed such that the output of the inverter 12 of the latch 18 is set to “1”. As the clock signal +BCK and its inverted signal −BCK return to HIGH and LOW, respectively, the data stored in the latch 18 is stored in the latch 19, so that the scan output +SO is set to “1”. In this manner, the first flip-flop is set to an initial value of “0”, and the second flip-flop is set to an initial value of “1”.

In the scan operation mode, data at the scan input +SI is loaded to the latch 18, and the loaded data is then transferred to the latch 19, followed by outputting the transferred data at the scan output +SO. In this scan operation mode, the clock signal +CK is fixed to LOW (i.e., its inverted signal −CK is fixed to HIGH). Further, the reset signal +RST is fixed to LOW (i.e., its inverted signal −RST is fixed to HIGH). In this state, the clock signal +ACK and the clock signal +BCK are alternately set to HIGH to cause data to be loaded to the latch 18 and the data to be subsequently transferred from the latch 18 to the latch 19. Each time a HIGH pulse appears in the clock signal +BCK the data of the scan output +SO is switched to new data.

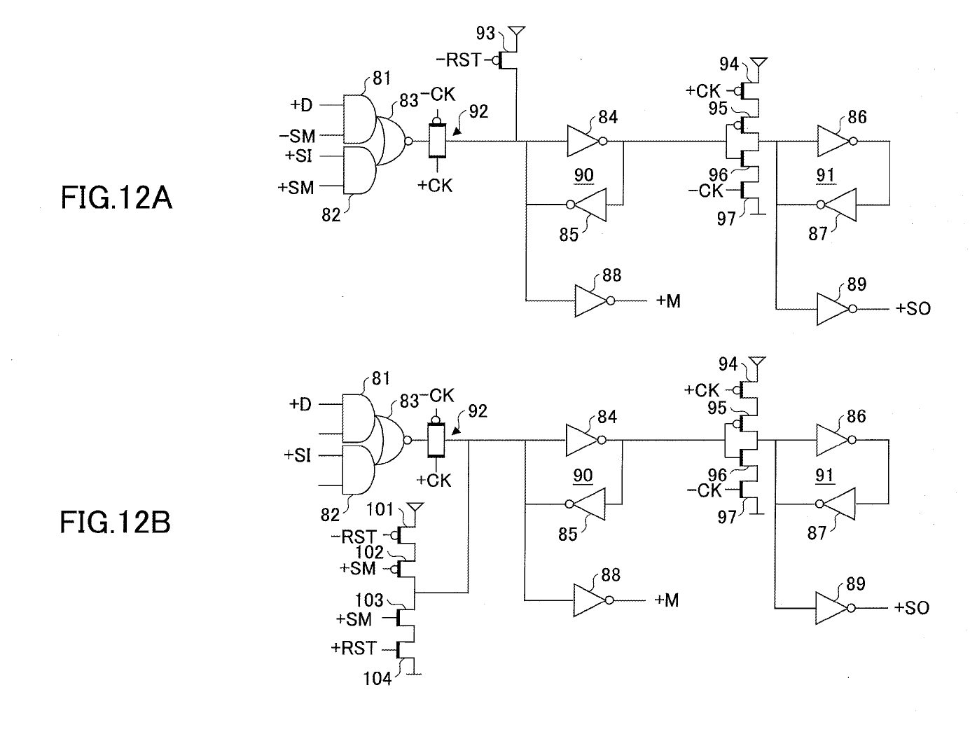

FIGS. 12A and 12B are drawings illustrating the configuration of an embodiment of flip-flops provided with the MUX-D-type scan function. The flip-flop illustrated in FIG. 12A includes AND gates 81 and 82, a NOR gate 83, inverters 84 through 89, a transmission gate 92, PMOS transistors 93 through 95, and NMOS transistors 96 and 97. The flip-flop illustrated in FIG. 12B differs from the flip-flop illustrated in FIG. 12A in that the PMOS transistor 93 is removed and in that PMOS transistors 101 and 102 and NMOS transistors 103 and 104 are added. Other configurations are the same or similar between the flip-flop illustrated in FIG. 12A and the flip-flop illustrated in FIG. 12B.

Each of the inverters 84 and 85 receives the output of the other as its input, so that these inverters function as a latch 90. Further, each of the inverters 86 and 87 receives the output of the other as its input, so that these inverters function as a latch 91.

The transmission gate 92 includes a PMOS transistor and an NMOS transistor that are connected to each other in parallel. The transmission gate 92 becomes conductive when a clock signal +CK is HIGH (i.e., its inverted signal −CK is LOW). As the transmission gate 92 becomes conductive, an inverse of the data input +D is stored in the latch 90 when the scan mode signal +SM is LOW (i.e., its inverted signal −SM is HIGH) to indicate the normal operation mode rather than the scan operation mode. An inverse of the scan input +SI is stored in the latch 90 when the scan mode signal +SM is HIGH (i.e., its inverted signal −SM is LOW) to indicate the scan operation mode. Thereafter, the clock signal +CK is set to LOW (i.e., its inverted signal −CK is set to HIGH) to transfer the data stored in the latch 90 to the latch 91.

The flip-flop with the scan function illustrated in FIG. 12A is a first flip-flop that has a circuit configuration capable of setting “0” as an initial value. Namely, this first flip-flop is initialized such that the scan output +SO is set to “0”. This flip-flop includes a first logic circuit (i.e., a PMOS transistor 93), and receives a plurality of control signals (i.e., +CK, +SM, −RST) in addition to the scan input signal +SI and the data input signal +D that are to be latched. Inverses of the signals +CK, +SM, and −RST may be generated by use of inverters, which are omitted from illustration. The plurality of control signals only include the one-bit reset signal −RST and the control signals +CK and +SM whose purposes (i.e., the clock synchronization purpose and the scan mode indication purpose in this example) are other than the initialization purpose. More specifically, the plurality of control signals are the one-bit reset signal −RST, the clock signal +CK for inputting and outputting a data input signal, and the scan mode signal +SM for indicating the scan mode. Setting the plurality of control signals to a certain combination of logic values causes the first scan flip-flop illustrated in FIG. 12A to be initialized to “0” by the first logic circuit (i.e., the PMOS transistor 93).

The flip-flop with the scan function illustrated in FIG. 12B is a second flip-flop that has a circuit configuration capable of setting “1” as an initial value. Namely, this second flip-flop is initialized such that the scan output +SO is set to “1”. This flip-flop includes, instead of the first logic circuit (i.e., the PMOS transistor 93), a second logic circuit (i.e., PMOS transistors 101 and 102 and NMOS transistors 103 and 104). Further, this flip-flop receives the previously-noted plurality of control signals (i.e., +CK, +SM, −RST) in addition to the scan input signal +SI and the data input signal +D that are to be latched. Inverses of the signals +CK, +SM, and −RST may be generated by use of inverters, which are omitted from illustration. Setting the plurality of control signals to a certain combination of logic values causes the second scan flip-flop illustrated in FIG. 12B to be initialized to “1” by the second logic circuit (i.e., the PMOS transistors 101 and 102 and the NMOS transistors 103 and 104).

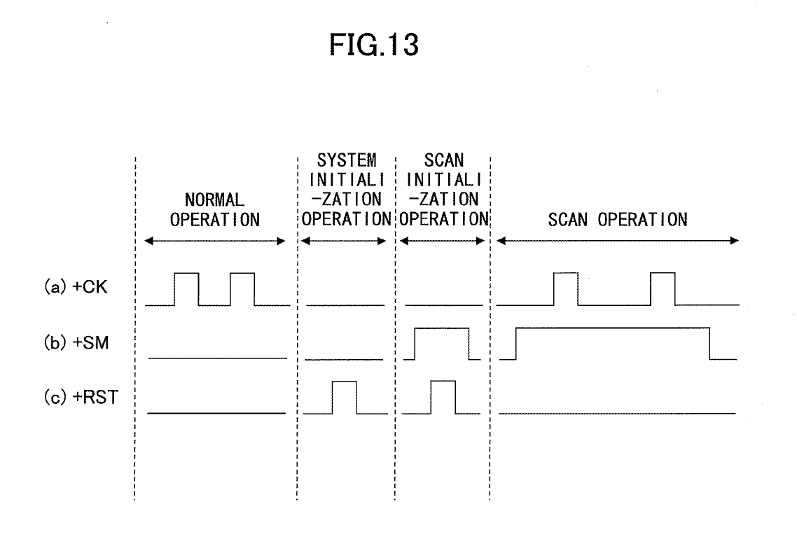

FIG. 13 is a timing chart illustrating the waveforms of input signals used in each operation mode of the flip-flops with the scan function illustrated in FIGS. 12A and 12B. FIG. 13-(a) illustrates +CK, and FIG. 13-(b) illustrates +SM, with FIG. 13-(c) illustrating +RST.

In the normal operation mode, the latch 90 loads data at the data input +D, and outputs the loaded data at the data output +M. In this normal operation mode, the scan mode signal +SM is fixed to LOW (i.e., its inverted signal −SM is fixed to HIGH), and the reset signal +RST is fixed to LOW (i.e., its inverted signal −RST is fixed to HIGH). In this state, the clock signal +CK is set to HIGH and LOW alternately. The latch 90 loads the data input +D at the time the clock signal +CK is HIGH (i.e., its inverted signal −CK is LOW). The data of the latch 90 is transferred to the latch 91 at the time the clock signal +CK subsequently becomes LOW (i.e., its inverted signal −CK is HIGH). The data stored in the latch 90 is output as the data output +M, and the data stored in the latch 91 is output as the scan output +SO.

In the system initialization operation, initialization is performed to reset the entirety of the LSI 43 illustrated in FIG. 8, for example. In this system initialization operation, the clock signals +CK and the scan mode signal +SM are fixed to LOW. In this state, the reset signal +RST is set to HIGH (i.e., its inverted signal −RST is set to LOW), thereby performing a reset operation. Specifically, the flip-flop with the scan function illustrated in FIGS. 12A and 12B is initialized such that the input node of the inverter 84 of the latch 90 is set to “1”.

In the initialization operation of the scan operation mode, the flip-flops with the scan function illustrated in FIGS. 12A and 12B are initialized to “0” and “1”, respectively. In the scan operation mode, the clock signal +CK is fixed to LOW (i.e., its inverted signal −CK is fixed to HIGH). In the initialization operation, the scan mode signal +SM is set to HIGH (i.e., −SM is set to LOW), followed by setting the reset signal +RST to HIGH (i.e., setting −RST to LOW). Thereafter, the reset signal +RST is returned to LOW (i.e., −RST is returned to HIGH), followed by returning the scan mode signal +SM to LOW (i.e., returning −SM to HIGH). With this arrangement, the PMOS transistor 93 in the first flip-flop with the scan function illustrated in FIG. 12A becomes conductive in response to the LOW state of −RST, so that the latch 90 is initialized. Namely, initialization is performed such that the output of the inverter 84 of the latch 90 is set to “0”. Since the clock signal +CK and its inverted signal −CK are LOW and HIGH, respectively, the data stored in the latch 90 is immediately stored in the latch 91 also, so that the scan output +SO is set to “0”. Further, the NMOS transistors 103 and 104 in the second flip-flop with the scan function illustrated in FIG. 12B become conductive in response to the HIGH state of +RST and +SM, so that the latch 90 is initialized. Namely, initialization is performed such that the output of the inverter 84 of the latch 90 is set to “1”. Since the clock signal +CK and its inverted signal −CK are LOW and HIGH, respectively, the data stored in the latch 90 is immediately stored in the latch 91 also, so that the scan output +SO is set to “1”. In this manner, the first flip-flop is set to an initial value of “0”, and the second flip-flop is set to an initial value of “1”.

In the scan operation mode, data at the scan input +SI is loaded to the latch 90, and the loaded data is then transferred to the latch 91, followed by outputting the transferred data at the scan output +SO. In this scan operation mode, the scan mode signal +SM is fixed to HIGH (i.e., its inverted signal −SM is fixed to LOW). Further, the reset signal +RST is fixed to LOW (i.e., its inverted signal −RST is fixed to HIGH). In this state, the clock signal +CK is set to HIGH and LOW alternately to cause data to be loaded to the latch 90 and the data to be subsequently transferred from the latch 90 to the latch 91.

According to at least one embodiment of the present disclosures, a scan circuit and a semiconductor integrated circuit are provided that allow the location of a failure to be readily identified.

Further, the present invention is not limited to these embodiments, but various variations and modifications may be made without departing from the scope of the present invention.

In the above-described embodiments, a description has been given of examples of the LSSD method and the MUX-D method with respect to the circuit configuration of flip-flops that can be independently set to an initial value of “0” and an initial value of “1”. Notwithstanding this, the present invention is not limited to the LSSD method and the MUX-D method. The technology disclosed in this application may be applied to a configuration of any method for which a plurality of control signals supplied to a flip-flop include only a one-bit reset signal and control signals whose purposes are other than the initialization purpose. Namely, either a first logic circuit for setting an initial value to “0” or a second logic circuit for setting an initial value to “1” may be provided so that setting the plurality of control signals to a predetermined combination of logic values causes the first logic circuit or the second logic circuit to set the initial value. The technology disclosed in this application presumes the existence of a flip-flop of a predetermined scan test method, and then uses only the existing control signals used in the predetermined method as control signals supplied to the flip-flop to allow an initial value to be independently set to “0” and “1”.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A scan circuit, comprising:
a plurality of first scan flip-flops each including a first logic circuit and each configured to receive a plurality of control signals in addition to a scan input signal and a data input signal that are to be latched; and
a plurality of second scan flip-flops each including a second logic circuit and each configured to receive the plurality of control signals in addition to a scan input signal and a data input signal that are to be latched,
wherein the first scan flip-flops and the second scan flip-flops are connected in series, and the plurality of control signals include only a one-bit reset signal and control signals whose purpose is other than an initialization purpose, and wherein the plurality of control signals are set to a predetermined combination of logic values to cause each of the first scan flip-flops to be initialized to “0” by the first logic circuit and to cause each of the second scan flip-flops to be initialized to “1” by the second logic circuit.

2. The scan circuit as claimed in claim 1, wherein the first scan flip-flops and the second scan flip-flops are connected in series to alternate with each other.

3. The scan circuit as claimed in claim 1, wherein the plurality of control signals are signals used in a MUX-D method or signals used in an LSSD method.

4. The scan circuit as claimed in claim 1, wherein the plurality of control signals include the one-bit reset signal, a first clock signal for inputting and outputting the data input signal, and second and third clock signals for inputting and outputting the scan input signal.

5. The scan circuit as claimed in claim 1, wherein the plurality of control signals include the one-bit reset signal, a clock signal for inputting and outputting the data input signal, and a scan mode signal for indicating a scan mode.

6. A semiconductor integrated circuit, comprising:
a scan input terminal;
a scan output terminal;
a plurality of first scan flip-flops each including a first logic circuit and each configured to receive a plurality of control signals in addition to a scan input signal and a data input signal that are to be latched; and
a plurality of second scan flip-flops each including a second logic circuit and each configured to receive the plurality of control signals in addition to a scan input signal and a data input signal that are to be latched; and
a circuit connected to the plurality of first scan flip-flops and to the plurality of second scan flip-flops,
wherein the first scan flip-flops and the second scan flip-flops are connected in series between the scan input terminal and the scan output terminal, and the plurality of control signals include only a one-bit reset signal and control signals whose purpose is other than an initialization purpose, and wherein the plurality of control signals are set to a predetermined combination of logic values to cause each of the first scan flip-flops to be initialized to “0” by the first logic circuit and to cause each of the second scan flip-flops to be initialized to “1” by the second logic circuit.

7. The semiconductor integrated circuit as claimed in claim 6, wherein the first scan flip-flops and the second scan flip-flops are connected in series to alternate with each other.

8. The semiconductor integrated circuit as claimed in claim 6, wherein the plurality of control signals are signals used in a MUX-D method or signals used in an LSSD method.

9. The semiconductor integrated circuit as claimed in claim 6, wherein the plurality of control signals include the one-bit reset signal, a first clock signal for inputting and outputting the data input signal, and second and third clock signals for inputting and outputting the scan input signal.

10. The semiconductor integrated circuit as claimed in claim 6, wherein the plurality of control signals include the one-bit reset signal, a clock signal for inputting and outputting the data input signal, and a scan mode signal for indicating a scan mode.
